(19) United States
(12) Patent Application Publication
(10) Pub. No.: US 2011/0308847 A1
(43) Pub. Date: Dec. 22, 2011

(54) Method for high-temperature circuit board assembly

(76) Inventor: Randy Allen Normann, Edgewood, NM (US)

(21) Appl. No.: 12/803,184

(22) Filed: Jun. 21, 2010

(51) Int. Cl. H05K 1/11; B23K 1/20; B23K 31/02; H05K 1/02; H05K 1/18

(52) U.S. Cl. 174/258; 174/260; 174/263; 228/179.1; 228/262; 228/256

(57) ABSTRACT

The creation of a circuit board which contains electrical interconnections between the circuit board traces and electronic devices mounted on the circuit board where the circuit board assembly can be operated at temperatures of 600° C. or greater. This invention allows for solder connections to be formed using solder paste or high-temperature.

### PRIORITY

The present application claims priority from commonly owned and assigned provisional application by Randy A. Normann, entitled “Method for High-Temperature Circuit Board Interconnects” sent in to the Commissioner of Patents, PO Box 1450, Alexandria, Va. on May 18, 2010. This document is incorporated herein by reference.

### FIELD OF THE INVENTION

A means for creating conductive metal interconnections for electronic circuit components on a circuit board used for temperatures as high as 600° C.

### DESCRIPTION OF PRIOR ART

Almost from the beginning of electrical circuits, lead based solders have been used to connect to circuit conductors together. Circuit boards comprise a plurality of electrical conductive metal traces separated by an electrical insulated material. In general, circuit boards having a top surface and a bottom surface with metal foil traces used as electrical conductors. A system of plated through-holes and surface mounting pads are used as mounting locations for electronic components on to the circuit board. The components are physically and electrically connected to the circuit board and conductive traces by soldering. Soldering is performed by placing molten metal on the electronic component termination and the corresponding plated through-hole or surface mounting pad and letting the molten metal cool back to a solid metal. Circuit boards were designed to meet the solder needs of standard 60/40 (60% tin, 40% lead) solder with a melting point of 183° C.

Today, standard 60/40 solder is being replaced with lead-free solders. In many countries, lead solder is prohibited by RoHS, ‘Restriction of Hazardous Substances Directive’. Lead-free solders in commercial use may contain tin, silver, bismuth, indium, zinc, copper, antimony, and other metals. These solders are normally increasing the melting point between 200° C. and 225° C.

The act of soldering electrical conductors normally involves flux. Flux is a reducing agent needed to reduce oxidization of the molten metal solder. The use of flux improves the flow of molten metal, improving the electrical connection and the mechanical strength of the connection over simple molten metal alone.

However, higher temperature solders are not easy to work with. First, the fluxes tend to be liquid based to bum off too fast during the soldering process. Secondly, as the melting point of solder increases, the potential for damaging the electronic components or the mounting circuit board increase. For example, ceramic capacitors can be damaged by thermal stress created during high-temperature solder process without showing any initial fault. This damage leads to a shortened end-of-life failure perhaps only a few 100 hrs after the product is released creating a warrantee issue.

As a result, the solders are not heated beyond their melting point which leads to molten solders having poor flow qualities. Manual soldering of high temperature solders can lead to increased errors such as open circuits and unintended shorting by solder extending over the circuit board insulator between adjacent but otherwise isolated conductors.

A good illustration of the problems with higher temperature lead-free solders is noted in U.S. Pat. No.: 7,637,415, Dec. 29, 2009, Holmes. This patent describes the circuit board and a process of mounting electronic components on the board with lead free solder. However, their process is limited to wave soldering not hand soldering.

Hand solder is improved by placing a number of via holes at the location of the connective circuit lead needs to be soldered to the metal foil traces on the circuit board. The via holes allow heat to more easily travel through the circuit board which can encourage the solder to flow better. An example of this is found in U.S. Pat. No. 7,554,040, Nakao, et al. An issue with this method is the need to decrease board cost as board manufacturing cost is a function of board size and the number of holes being drilled.

Another soldering process uses solder paste. Solder paste is formed by blending an alloy or pure metal powder with a liquid flux. The alloy powder is composed of very small metal particles. When the solder paste is heated, the flux is burned or baked off and the metal powder fuses together to create a solid connective solder joint. In many cases, the initial temperature required to fuse the metal particles together is lower than the temperature required to reflow the metal after the flux is baked off. An example of solder paste can be found in U.S. Pat. No. 7,681,777, Hirata, et al.

The use of solder paste offers the advantage of creating a solder joint at a lower temperature than the reflow or re-melting of the solder. The powders within the flux can form a solder joint at lower temperatures which are safer for the electronic components and still form a strong solder joint operating at higher temperatures. Some solder pastes have an initial heat requirement of 250° C. to bake off the flux while the reflow temperature can be over 600° C.

U.S. Pat. No. 7,637,412, Koopmans is a good example of a method using solder paste on a circuit board with a plurality of electronic components. Here, a method of depositing and reflowing solder paste using a stencil. The disadvantage of this system is the repeated use of the application of solder paste. The stencil creates solder paste locations on the circuit board for locating components mounting positions and then a second pass is needed to complete connection to the actual components.

An electrical interconnection process used to eliminate the soldering process is to use conductive epoxies. Here conductive metal particles are suspended in an epoxy. As the epoxy is cured, it hardens and maintains electrical connection between electrical conductors. Conductive epoxies can be used for electrical connection on a circuit board. Conductive epoxies have the advantage of not over heating the electronic components during curing but after curing can maintain a solid electrical connection at elevated temperatures. Conductive epoxies have a particular advantage for connecting ceramic capacitors to a circuit board.

Circuit boards were originally designed for standard solders and not solder paste or conductive epoxy. FIGS. 1 through 4 illustrate standard hand soldering on a circuit board using circuit board cut-away illustrations of a through-hole solder joint. FIG. 1 shows a conductive lead (C) going through a plated through-hole (J) in a circuit board (A). The circuit board hole has a plated through hole of conductive metal which is attached to conductive foil traces (B) on both sides of the board. These conductive foil traces are on the top and bottom of the circuit board's surfaces. In FIG. 2, a soldering iron (D) is used to heat both the conductive lead and the circuit board conductors (B) at the hole. Once the lead and the circuit board hole have been heated, a stick of solder (E) in FIG. 3 is applied. In many cases, the stick of solder (E) has a center filled with solder flux. Once the solder has melted and flows around the wire and through the circuit board hole, the solder iron is removed along with the stick of solder. FIG. 4, illustrates the final product of a conductive lead (C) electrically connected to circuit board traces (B).

Both solder paste and conductive epoxies require placing the conductive bonding materials in place and then heating or curing the material. This requires the solder paste and conductive epoxy to have a high viscosity. The existing circuit board concepts simply work against this process. Getting high viscosity materials to flow down the circuit board hole requires effort by the technician. Also, if during the placement of solder paste or conductive epoxy the circuit board component moves or the circuit board is bumped, the conductive materials can move creating shorts or open circuits in the final product. I discovered that both of these issues can be solved by designing the circuit board for solder paste or conductive epoxies.

### SUMMARY OF THE INVENTION

The invention creates reservoirs around circuit board electrical conductors needing an electrical connection to greatly simplify the application of high temperature solders and solder pastes. These types of electrical connections are difficult to produce reliably on conventional circuit boards having circuit traces and mounting pads on the surface of the circuit board's insulating material. The development of recesses in the circuit board's insulator for circuit board traces, plated through-holes and solder pads allows for the creation of reservoirs in the circuit board to contain solder or solder paste next to conductors needing an electrical connection.

The invention offers benefits to both machine assembly and hand assembly. Where hand assembly of very high-temperature circuit boards with a large number of electrical interconnections leads to assembly errors working with conventional circuit boards with surface traces and mounting pad and holes. The inventor has demonstrated circuit boards with a plurality of soldered connections operating >500° C.

### BRIEF DESCRIPTION OF THE DRAWINGS

FIG. 1 is a cut-through illustration of a circuit board with surface traces, a plated through-hole and a wire running through the hole.

FIG. 2 is a cut-through illustration of a circuit board with surface traces, a plated through hole and a wire running through the hole. The hot point of a soldering iron is shown heating the wire and the circuit board plated through-hole.

FIG. 3 is an extension of FIG. 2. A solid wire of solder is being applied to the hot wire and plated through-hole of the circuit board. As the solid wire is fed to the circuit board, molten solder is being created.

FIG. 4 is the final phase of soldering illustrated in FIGS. 1, 2 and 3. The solder iron and the solid wire of solder are both removed and the solder joint is allowed to cool creating a solid electrical connection between the circuit board and the wire.

FIG. 5 is a cut-through illustration of a wire, a plated hole and conductive traces. However, now the plated through-hole and conductive traces are recessed below the surface of the non-conductive circuit board base material.

FIG. 6 is an illustration of the final product of FIG. 5. The solder paste has been applied.

FIG. 7 is an cut-through illustration of an electronic device being soldered to recessed board pads and traces by cutting out a recess allowing for the device to fit.

FIG. 8 is a cut-through illustration of an electric device being soldered to conductive pads and traces recessed in the circuit board by using enough solder paste to fill the recess up to the metal contacts on the device.

### DETAILED DESCRIPTION OF THE PRESENT INVENTION

FIG. 5 is a cut-though illustration of the invention. The conductive foil traces normally placed on the top and bottom of the insulating circuit board material are actually recessed below the surface of the circuit board. The mounting holes and solder pads are also recessed. Now, the insulating circuit board material is creating a reservoir for containing the solder paste. The recesses help contain the solder paste until a solid electrical connection can be formed. Forming a solid solder connection normally requires heating the circuit board and solder paste until the solder paste becomes a solid solder joint between the circuit components and the circuit board traces. A solid solder connection is shown in FIG. 6.

By using a high-temperature ceramic as the insulating material of the circuit board the operating temperature of the circuit assembly is only limited by the melting point of the metal conductive traces and the reflow temperature of the solder joints. In one embodiment of this invention, a nickel based alloy was used for circuit board traces with a melting point >1000° C. and a solder paste using a silver based alloy with a reflow temperature >600° C. on a ceramic insulated circuit board rated >800° C. created a circuit assembly rated to 600° C.! Here the 600° C. can be either the ambient temperature of the circuit board or the local junction temperature of any electronic device or any combination of heat sources.

For high viscosity solder paste, this process can be repeated for both sides of the circuit boards independently or together. This assures connection between both sides of the circuit board for each conductive lead.

A variation of this process is to use the solder paste as both the metal for creating the circuit connections and also as conductive trace on the circuit board. Here the recesses do not initially contain circuit traces. The solder paste is used to fill the circuit board recesses to form the conductive traces between circuit connections. This variation offers a reduction in intermetallic activity as the circuit board trace and connecting metals are the same metals.

An obvious variation is the use of conductive inks in place of solder paste. For the purposes of this invention, conductive inks and solder paste are the same materials with the only difference found in their application. Conductive inks are used to paint conductive traces and create conductive bonds while solder paste is used in larger bulk quantities to replace standard soldering processes.

Another variation of this process is using circuit board traces created from any process which places the conductive traces inside recesses in the insulating material of the circuit board. A plating process may place conductive material on all three sides of the circuit board recess channel. Also a simple wire could be placed in the recess of the circuit board. A unique method for placing a conductive circuit trace in a circuit board recess using thermal spray of metal is given in patent application “Method for High-Temperature Ceramic Circuits”, Randy A. Normann, attorney docket number RAN001.

Another variation of this process is for small surface mounted electronic devices. These devices normally mount by soldering directly to foil traces or solder pads on top of a conventional circuit board. Using the invention, there are two means to accomplish mounting surface mounted devices using recessed circuit board traces.

The first means of mounting surface mounted electronic devices is to recess the device into the circuit board down to the circuit board traces. FIG. 7 is a cut-through illustration of this process for a surface mounted capacitor (G). Capacitor (G) has two electrical terminations shown as (H). The solder paste is shown as (F).

The second means of mounting a surface mounted electronic device is to simply use enough solder (F) to fill the circuit reservoir allowing for electrical connection between the circuit board traces (B) and the electronic device terminals (H). A cut-though illustration of this method is shown in FIG. 8.

Where circuit board traces are recessed and there is not a need to solder or to make an electrical connection to an electronic device or conductive lead, filler can be used to fill in the recess on top of the conductive trace. The filler can be either conductive or non-conductive. The use of a filler material is illustrated in FIGS. 7 and 8 as item (I). The use of a filler material aids in reducing use of solder paste by completing the sides of the reservoir around the conductive lead or electronic device. Filler can also be used after the soldering process is completed to aid in keeping the metal traces in place at higher temperatures. The thermal expansion of metal is normally greater than the thermal expansion of nonconductive board materials.

To aid in the flow of solder paste, an air pressure differential can be used. For the example shown in FIGS. 5 and 6, a pressure differential of air created across the circuit board hole containing the wire shown in FIG. 5 will draw or push the solder paste through the hole connecting both sides of the circuit board shown in FIG. 6.

Another variation of a process aiding in the flow of solder paste is to vibrate or shake the circuit board while the solder paste is still in a liquid state.

A benefit of flowing solder paste through circuit board holes is the elimination of conventional plated through-holes. Conventional circuit boards use a plating method to create a metal layer on the sides of a circuit board hole. This assures electrical connection between both sides of the circuit board and it also improves conventional solder flow. By flowing the solder paste through the hole, the need for a plated through-hole is eliminated.

An example embodiment of this invention is using a milling or etching process to create recesses in a ceramic insulating material. Metal is then deposited, partially filling the recesses. Electronic devices are then mounted on the ceramic board with their metal connections located in or just above circuit board electrical connection points. A solder paste is used to fill or nearly fill the recess surrounding the electrical connection between the electronic device and the circuit board traces. The circuit board and electronic devices are heated in an oven to the correct temperature to convert the solder paste to solid solder joints.

This invention yields seven benefits over conventional circuit construction methods.

1. Circuit boards with recessed circuit interconnecting traces and circuit pads allow for easy use of solder paste to create conductive joints between devices and conductive leads. Many solder pastes allow for the creating of a solid conductive solder joint at lower temperatures than most solders. This reduces the potential for damaging circuit components. In particular, multi-layer ceramic capacitors can be damaged by thermal stress caused by soldering.

2. There is less risk of solder paste flowing onto adjacent circuit elements creating a short circuit because of the reservoir created by the recessed circuit traces and circuit pads.

3. There is less risk of solder paste flowing away from the desired circuit elements creating an open circuit. The reservoir created by the recessed circuit traces and circuit pads help maintain the solder paste in its proper location until the initial processing is completed.

4. By using a solder paste with a reflow temperature higher than the initial soldering temperature, either side of the circuit board can be soldered independently.

5. The same process is undertaken for hand assembly as machine assembly. The solder paste is placed at the location for interconnection between circuit elements. Any portion or the entire circuit board with a plurality of circuit connections can be heated at one time.

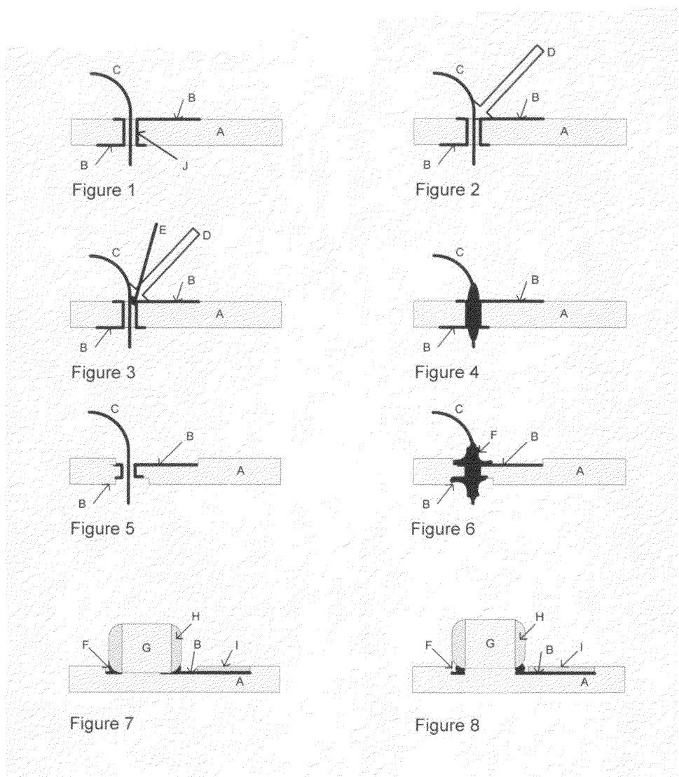

6. By heating the entire board and circuit components with the solder paste, there is less thermal stress placed on the circuit board and components than created by hand soldering where heating is local as can be seen in FIGS. 1 through 4.

7. The reservoir containing the solder paste also increases the shear strength of the solder joint. Shear strength is the required pressure needed to push an electronic device until the solder joint fails. Here the sides of the circuit board strengthen the solder joint.

The particular sizes and equipment discussed above are cited merely to illustrate particular embodiments of the invention. It is contemplated that the use of the invention can involve components having different sizes and characteristics. It is intended that the scope of the invention be defined by the claims appended hereto. The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention.

What is claimed is:

1. A method for circuit board assembly where electrical connections between conductors on a circuit board are created in recesses in the insulating material of the circuit board to contain the solder paste when creating a solder joint between the conductors.

2. The electrical connections of claim 1, wherein the circuit board insulating material is a high-temperature ceramic, the circuit board conductors are made from high-temperature metal or a metal alloy and the solder paste is based on a high-temperature metal or a metal alloy allowing the circuit board assembly to be operated at 600° C. or greater.

3. The electrical connection of claim 1, wherein one of the conductors is from an electrical device and that electrical device is also placed in the recess of the circuit board containing the electrical trace.

4. The electrical connection of claim 1, wherein one of the conductors is from an electrical device which is placed on top of the circuit board and solder paste is used to fill the recess making electrical connection to the electronic device.

5. The electrical connection of claim 1, wherein the recesses in the circuit board are filled with insulating material after the solder process is complete.

6. The electrical connection of claim 1, wherein the recesses in the circuit board are filled with additional conductive material after the solder process is complete.

7. A means for aiding the flow of a molten solder or solder paste vibrating or shocking the circuit board.

8. A method of claim 7, wherein the vibration is replaced by or aided by a difference in air pressure above and below the circuit board.

9. A method of claim 7, wherein the flowing molten solder or solder paste is used to replace the plating process used to create plated through-holes in circuit boards.

10. A method of creating circuit board conductive traces by placing molten metal into recesses in the insulating material of the circuit board and allowed to cool to create solid conductive traces.

11. A method of claim 10, wherein solder paste is placed into the recesses of the circuit board and heated to create solid conductive traces.

12. A method of claim 10, wherein conductive epoxy is place into the recesses of the circuit board and cured to create solid conductive traces.
